(19) United States
(12) Patent Application Publication
(10) Pub. No.: US 2021/0071417 A1
(43) Pub. Date: Mar. 11, 2021

(54) Curved LED Tile

(71) Applicant: Aluvision N.V., Deinze (BE)

(72) Inventor: Dirk Deleu, Deinze (BE)

(21) Appl. No.: 16/567,645

(22) Filed: Sep. 11, 2019

(51) Int. Cl. E04B 2/74; H05K 5/00; H05K 5/02; E04B 2/76

(52) U.S. Cl. CPC E04B 2/7416; H05K 5/0017; E04B 2/76; H05K 5/0204; H05K 5/0021

(57) ABSTRACT

Building element for a modular construction, the building element comprising at least one LED module, the building element further comprising a curved frame with a connection surface for the at least one LED module, wherein the LED module comprises a flexible substrate one side of which is provided with a LED display and the other side of which is provided with connection means to connect the flexible substrate with the curved frame.

### BACKGROUND

### Field of the Technology

The present invention relates to a building element for a modular construction.

### Description of the Prior Art

WO2018/116101 describes a display module for a temporary exhibition stand. A modular temporary exhibition stand is a temporary building which consists of several walls and can be constructed or dismounted and removed rapidly when needed, wherein the main components have a modular design and are usually frame modules provided with installation holes. The display module comprises a frame and a LED screen.

### BRIEF SUMMARY

Embodiments of the invention relate to a building element for a modular construction, the building element comprising the at least one LED module, the building element further comprising a curved frame with a connection surface for the at least one LED module, wherein the LED module comprises a flexible substrate one side of which is provided with a LED display and the other side of which is provided with connection means to connect the flexible substrate with the curved frame.

The combination of a LED module that is connected to a curved frame increases the ability to build a modular construction with a dynamic appearance. Because the LED modules connect to a connection surface of a curved frame, the LED display adapts to the shape of the curved frame. This results in a curved surface, the skin of which is a LED display. The outer appearance of such curved surface is adaptable by controlling the LED display. In a modular construction, curved surfaces can be integrated wherein at least a part comprises a LED display skin. This increases the modularity. It also increases the ability to create multiple structures having different shapes and sizes and outer appearances.

Preferably the curved frame is curved around an axis over about 360/N degrees, wherein N is a natural number between two and ten, preferably four.

Preferably the curved frame extends between two straight connection sides, which straight connection sides are provided with connection means to enable interconnection of adjacent curved frames.

Preferably the straight connection sides are compatible with adjacent non-curved elements.

Preferably the curved frame extends between two curved connection sides, which curved connection sides are provided with connection means to enable interconnection of adjacent curved frames

Preferably the at least one LED module comprises M identical LED modules, wherein M is a natural number between two and ten, preferably four.

Preferably each LED module comprises multiple magnets and wherein the curved frame comprises a magnetic surface to allow the LED modules to magnetically connect with the curved frame.

Preferably each LED module comprises positioning pins extending from the other side of the flexible substrate, the curved frame comprises perforations compatible with the positioning pins to enable positioning of the LED modules on the curved frame.

Preferably the curved frame comprises, opposite to the connection surface, a back surface, the back surface being provided with a groove extending around the periphery of the back surface to enable mounting of a back cover.

Preferably the back surface is additionally provided with handles to facilitate handling of the building element.

Preferably the back surface is provided with a power module for powering and controlling the LED modules.

Preferably the power module comprises a power input connection, a power throughput connection and comprises a signal input connection and a signal throughput connection.

Preferably the back surface is recessed with respect to a peripheral edge to enable a plate with a predetermined thickness to be mounted within the boundaries of the peripheral edge.

Preferably the connection surface is provided with an opening dimensioned to enable installing the building element from the front.

Preferably the curved frame comprises at least two support elements preventing the LED modules, when the curved frame is placed on a flat ground surface, to touch the ground.

Preferably the connection surface is convex. Alternatively the connection surface is concave.

### BRIEF DESCRIPTION OF THE DRAWINGS

The invention will now be described in more details with respect to the drawings illustrating some preferred embodiments of the invention. In the drawings:

FIG. 1 shows an exploded view of an embodiment of a building element;

FIG. 2 shows a frame of a further embodiment of a building element;

FIG. 3 shows a front view of the building element of FIG. 1;

FIG. 4 shows a led module usable in an embodiment of a building element;

FIG. 5 shows a construction wherein multiple building elements are integrated; and

FIG. 6 shows a detail of a back wall of an embodiment of a building element.

### DETAILED DESCRIPTION OF THE PREFERRED EMBODIMENTS

The following detailed description is directed to certain specific embodiments. However, the teachings herein can be applied in a multitude of different ways. In this description, reference is made to the drawings wherein like parts are designated with like numerals throughout.

The present invention will be described with respect to particular embodiments but the invention is not limited thereto but only by the claims.

As used herein, the singular forms “a”, “an”, and “the” include both singular and plural referents unless the context clearly dictates otherwise.

The terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited components, elements or method steps also include embodiments which “consist of” said recited components, elements or method steps.

Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the invention described herein are capable of operation in other sequences than described or illustrated herein.

Reference throughout this specification to “one embodiment”, “an embodiment”, “some aspects”, “an aspect” or “one aspect” means that a particular feature, structure or characteristic described in connection with the embodiment or aspect is included in at least one embodiment of the present invention. Thus, appearances of the phrases “in one embodiment”, “in an embodiment”, “some aspects”, “an aspect” or “one aspect” in various places throughout this specification are not necessarily all referring to the same embodiment or aspects, but may. Furthermore, the particular features, structures or characteristics may be combined in any suitable manner, as would be apparent to a person skilled in the art from this disclosure, in one or more embodiments or aspects. Furthermore, while some embodiments or aspects described herein include some but not other features included in other embodiments or aspects, combinations of features of different embodiments or aspects are meant to be within the scope of the invention, and form different embodiments or aspects, as would be understood by those in the art. For example, in the appended claims, any of the features of the claimed embodiments or aspects can be used in any combination.

Modular constructions are used for building movable and/or temporal structures. Examples where such modular constructions are mainly used comprise trade shows, fairs, concerts, temporal buildings, etc. In such modular constructions, the ability to exchange elements in the construction by other equivalent elements is a significant advantage. Also the ability to create multiple structures having different shapes and sizes and outer appearances, assembled with the same elements, is a significant advantage. Furthermore, the ability to efficiently mount and demount the construction is an advantage. Modularity implies a complementarity amongst multiple elements in the construction.

In modular constructions, there is a trend to increase the ability to exchange elements in the construction by other equivalent elements. This allows a designer and/or builder of such modular construction to change the outside appearance of the construction to choose amongst differently looking equivalent elements. There is also a trend to increase the ability to efficiently mount and demount the constructions. Embodiments of the invention aim to provide a new element that can be used in existing modular constructions. Therefore the new element is compatible with existing modular elements.

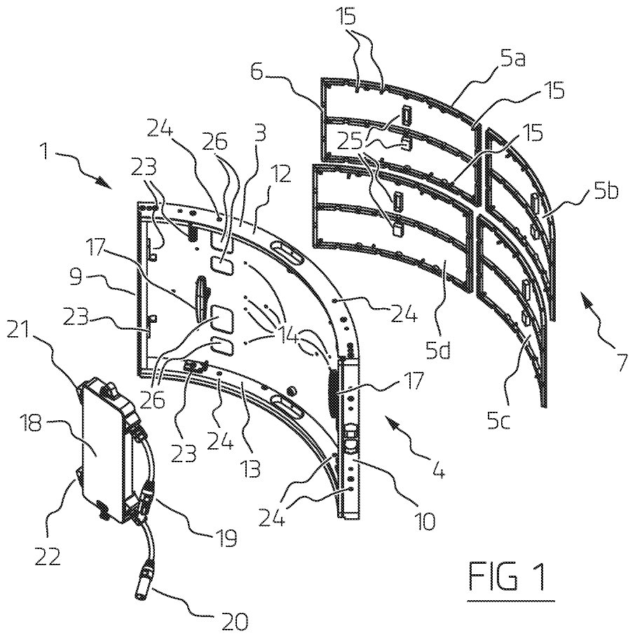

FIG. 1 shows an exploded view of a building element 1 according to an embodiment of the invention. The building element 1 is provided to be integrated into a modular construction, a simple example of which is shown in FIG. 5 and indicated with reference number 2. To this end, the building element is provided with connection elements and connection sides/walls, which will be further explained hereunder.

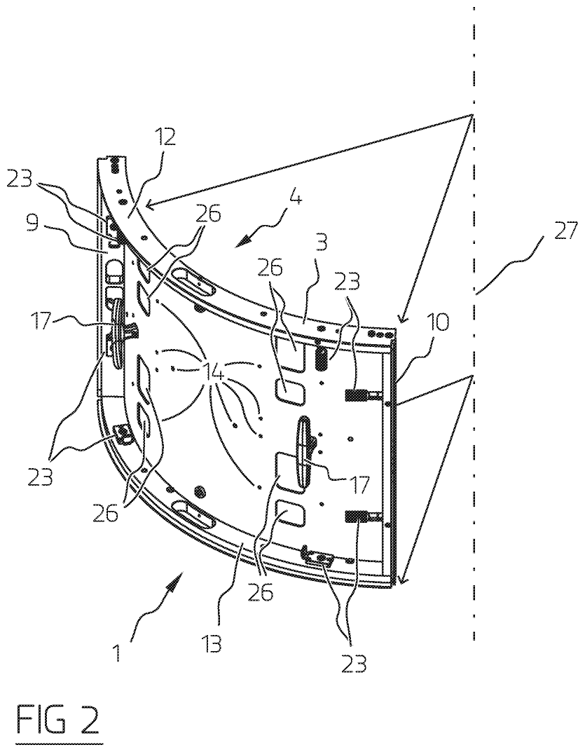

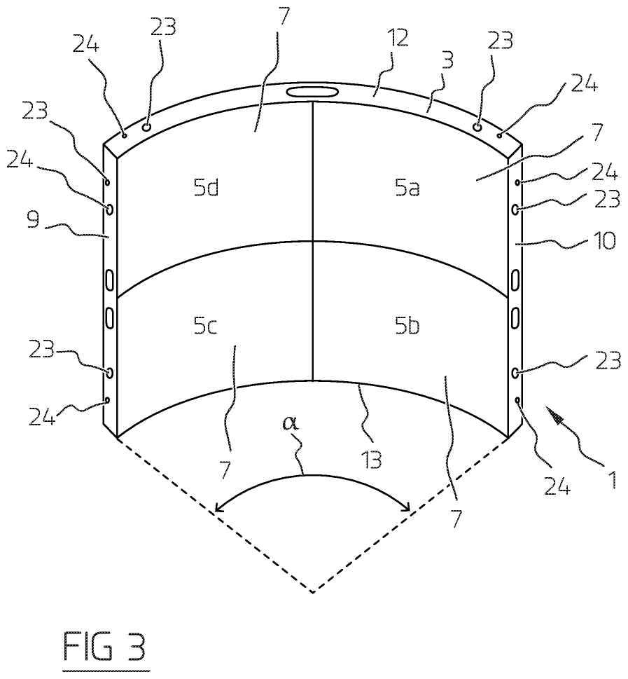

The building element 1 comprises a curved frame 3. The curved frame 3 is formed by a plate-like element which is bent and which is provided at its edges with border elements. The border elements define a framework around the plate-like element. The plate-like element and the framework together form the frame 3. With respect to the curve of the plate-like element, the framework can be directed towards the inside such that a convex frame 3 is obtained. FIG. 1 shows such convex frame 3. In another embodiment, the framework can be directed towards the outside such that a concave frame 3 is obtained. FIGS. 2 and 3 show such concave frame 3. The terms concave and convex are used to describe the curvature of the primary visible side of the frame 3 in the modular construction 2. This primary visible side is formed by the plate-like element.

The curved frame 3, and particularly the primary visible side of the frame 3, comprises a connection surface 4 for one or more LED modules 5. The connection surface 4 is preferably formed by a ferromagnetic material while the LED modules 5 are provided with magnets such that the LED modules 5 can magnetically connect to the connection surface 4. Alternatively is the connection surface 4 provided with a smooth surface finish and are the LED modules 5 provided with suction elements such that the LED modules 5 can connect to the surface 4 via suction. Further alternative, the connection surface 4 and LED modules 5 are provided with complementary snap-fit engagement elements such that the LED modules 5 can be snap-fitted to the connection surface 4.

In the embodiment of FIG. 1, the LED modules 5a, 5b, 5c and 5d comprise multiple positioning pins 15 protruding from the flexible substrate 6 of the LED module. These positioning pins 15 are complementary with perforations 14 in the connection surface 4 of the curved frame 3. The positioning pins 15 extend at least partially in or through the perforations 14 when the LED module is correctly positioned with respect to the connection surface 4. This facilitates the mounting and particularly the positioning of the LED modules on the connection surface 4. The person skilled in the art will understand that preferably two or more positioning pins 15 are provided at each LED module. Furthermore, the positioning pins are preferably asymmetrical so that the LED module can be fitted onto the connection surface 4 only in one orientation. This prevents the LED module to be placed upside down. Alternatively, the positioning pins and/or the perforations 14 are chosen to allow multiple positions and/or orientations of the LED modules 5 relative to the connection surface 4.

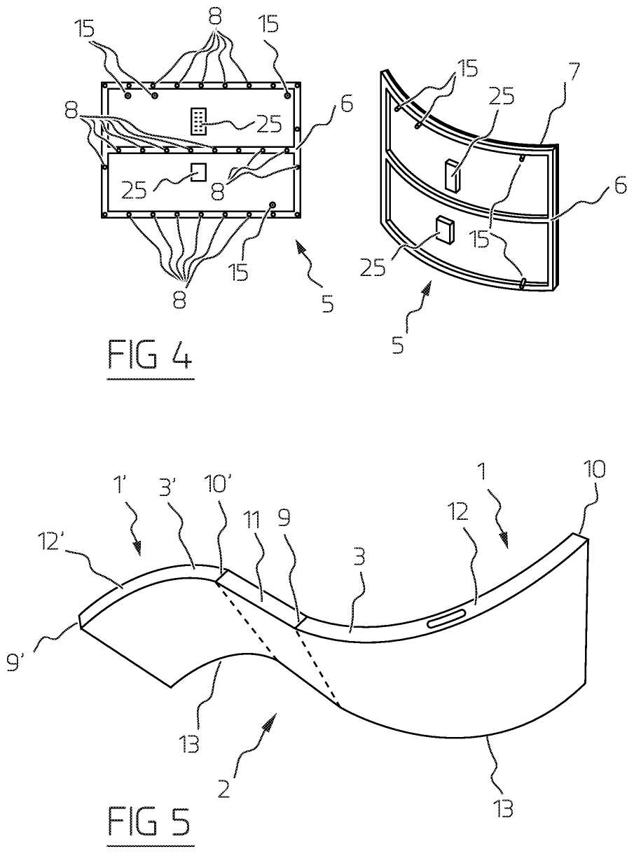

FIG. 1 shows four LED modules 5a, 5b, 5c and 5d. These four LED modules are preferably identical. The four LED modules together cover the complete connection surface 4 of the frame 3. When the connection surface 4 is covered by the LED modules, the frontal surface of the building element 1 is formed by a LED screen composed of the LED modules. The frontal surface is defined as the visible surface of the building element when the building element is integrated in a modular construction 2. The LED modules are preferably connected symmetrically to the connection surface 4. The person skilled in the art will understand that the number of LED modules is not limited to four, but can be any number. A single LED module can be provided with a surface area substantially equal in size and dimensions to the connection surface 4. Alternatively, two or three LED modules can be provided which are placed next to each other in a horizontal or vertical arrangement to cover the connection surface 4. In the same way, more than four LED modules can be provided and arranged in a pattern to cover the connection surface 4. The LED module 3 with magnets 8 provided in a flexible substrate 6 to which a LED display 7 is connected and wherein a signal connector 25 are provided, is described in more detail hereunder with reference to FIG. 4.

The framework provided around the plate-like element comprises a first straight connection side 9 and a second straight connection side 10. Furthermore, the framework provided around the plate-like element comprises a first curved connection side 12 and a second curved connection side 13. Each of the connection sides 9, 10, 12 and 13 is adapted to connect the building element 1 to an adjacent building element in the modular construction 2. In particular, each of the connection sides 9, 10, 12 and 13 are formed to lay flat against a corresponding one of the connection sides 9, 10, 12 and 13 of an identical element. Two sides laying flat against each other can be firmly interconnected via connector elements that are described hereunder. Sides laying against each other and firmly interconnected provide a high resistance against relative movement and/or rotation of the building elements with respect to each other such that a strong modular construction 2 can be made.

The plate-like element is bent and shows two substantially straight edges and two substantially bent edges. The first straight connection side 9 and second straight connection side 10 are provided at opposite straight edges of the plate-like element. The first curved connection side 12 and second curved connection side 13 are provided at opposite curved edges of the plate-like element.

Each one of the connection sides 9, 10, 12 and 13 is connected to the plate-like element and extends substantially perpendicular from this plate-like element. The connection surface 4 is considered the front side of the plate-like element and the connection sides 9, 10, 12 and 13 extend in the backward direction. The backward direction is the direction opposite to the front side direction. Each one of the connection sides 9, 10, 12 and 13 have a length, the length being substantially equal to the length of the corresponding edge of the plate-like element, a width, the width determining the thickness of the building element 1. At the back side of the building element 1, each one of the connection sides 9, 10, 12 and 13 is provided with a groove. The groove preferably extends around the complete periphery of the building element 1. This allows an element to be connected to the back side of the building element 1 to cover the elements and parts between the connection sides 9, 10, 12 and 13. In particular, a flexible cover can be tensioned over the back side of the building element 1, and a string-like element fitting in the groove can be used to connect the flexible cover to the back side of the building element 1. This allows to provide a visual finish to the back side thereby improving the appearance of the building element 1.

Each one of the connection sides 9, 10, 12 and 13 is provided with connector elements 23 and connection openings 24 to interconnect multiple building elements in a modular construction. The connector elements 23 are formed in pairs of complementary elements. The first straight connection side 9 is provided with a spring-loaded pin with a handle while the second straight connection side 10 is provided with an opening for the spring-loaded pin. The opening at the second straight connection side 10 is provided with a slidable collar and the pin is provided with a groove. Via the handle, the pin can be pushed through the opening such that the groove aligns with the collar. The collar can be slid over the groove to lock the pin in the opening. At this moment, the connection is made. In an analogue way, the first curved connection side 12 is provided with the spring-loaded pin with the handle and the second curved connection side 13 is provided with the opening with the slidable collar. More preferably, the connector elements 23 are provided at each connection side 9, 10, 12 and 13 in pairs such that each side has two spring-loaded pins and/or two openings with slidable collar. This is a preferred embodiment allowing building elements to be interconnected without external tools. An operator can manually interconnect the building elements via the connector elements 23.

Via the connection openings 24, screws or bolts can be used to interconnect adjacent building elements. In cases where at least one of the connection elements 23 is malfunctioning or absent, the connection openings 24 can be used to interconnect the building elements. Via the connection openings 24, building elements can also be connected to profiles or other elements used in the modular construction.

To improve the handling of the building element 1, handles 17 are provided in the embodiment of FIG. 1. The handles 17 are preferably provided at the back side of the plate-like element and have a height that is smaller than the thickness of the building element 1. This allows the handles to be covered by a cover connected to the back side of the building element 1.

The plate-like element is provided with a mounting structure for mounting a power module 18. The power module is provided with a power input 19 and a power throughput 20. Via the power input 19, the power module receives electrical power. Via the power throughput 20, the power module can provide power to an adjacent power module. The power input and power throughput 20 enable multiple power modules in a modular construction to be interconnected, providing all power modules with power in an efficient manner. The power module is preferably provided with a signal input 21 and a signal throughput 22. Via the signal input 21, the power module receives a control signal. Via the signal throughput 22, the power module can provide a control signal to an adjacent power module. The signal input 21 and signal throughput 22 enable multiple power modules in a modular construction to be interconnected, providing all power modules with a control signal in an efficient manner. The signal is generated by an external device (not shown) in a conventional manner as can be implemented by a person skilled in the art. The power modules can individually be provided with control signals and/or power. Preferably the input and throughput is used to interconnect multiple power modules, providing multiple power modules with power and/or control signals via a bus-like connection.

The power module 18 is further provided with a connector to each LED module 5. The LED module is provided with a signal connector 25, to which the power module connects. A signal cable and/or power cable is preferably used to interconnect the signal connector 25 and the power module 18.

The plate-like element is provided with openings 26. In the embodiment of FIG. 1, the openings 26 are shaped as signal connector openings allowing the signal connector 25 of each LED module 5 to be reached via the back side of the plate-like element. In other words, via the signal connector openings 25, the signal cable can extend from the signal connector 25 to the power module 18.

FIG. 2 shows a building element similar to the building element of FIG. 1. In the embodiment of FIG. 2, the building element 1 is concave. The figure shows that the building element is composed of highly similar parts, segments and elements including first and second straight connection sides 9, 10, first and second curved connection sides 12, 13, handles 17, the plate-like bent element having the perforations 14, signal connector openings 26 and the connection surface 4. Furthermore, FIG. 2 illustrates how the building element 1 is curved with respect to an axis 27. Because the axis 27 is located at the visible side, the building element is concave. In the embodiment of FIG. 1, the axis is located at the back side such that the building element is convex. Preferably the radius of curvature is constant to enhance the usability and interchangeability of building elements 1 in the construction.

FIG. 3 shows a front view of the building element 1 of FIG. 2. The figure illustrates that the building element 1 is curved over an angle α. This angle α is preferably about 90 degrees. Alternatively, the angle α can be 360/N degrees, wherein N is a natural number between two and ten, preferably four.

To enable placing the building element 1 on a ground surface and to minimize or prevent damage to the LED modules 5a, 5b, 5c, 5d, the lower curved connection side 13 is preferably provided with at least two, preferably three bulges functioning as spacers or support of the building element 1. Further preferably, the upper curved connection side 12 has corresponding indentations so that the bulges of an upper adjacent building element 1 can extend in the indentations allowing adjacent curved connection sides to lay against each other.

FIG. 4 shows a LED module. The LED module comprises a flexible substrate 6 having a back side and a front side. The front side is layered with a LED display 7, covering substantially the complete flexible substrate 6. The LED display 7 is a flexible LED display allowing the LED module 5 to be bendable. In particular, the LED module 5 is bendable to adopt at least the same curvature as the plate-like element.

The flexible substrate 6 is preferably provided with reinforcement ribs at least at the periphery of the flexible substrate. In the embodiment of FIG. 4, a further horizontal reinforcement rib is provided in a center of the substrate 6. The reinforcement ribs are preferably provided with holes wherein magnets are placed such that the substrate 6 can be magnetically connected to the connection surface 4. The substrate 6 is further provided with the positioning pins 6. In the embodiment of FIG. 4, the positioning pins are provided adjacent to the reinforcement ribs. The LED display 7 comprises the signal connector 25 to provide power and control signals to the LED display 7. The signal connector 25 is formed by two physical connectors in the embodiment of FIG. 4. The person skilled in the art will recognize that the signal connector 25 can be formed by one or physical multiple connectors in different forms using different protocols.

A LED module for a convex building element 1 is preferably different in shape as a LED module for a concave building element 1. To increase the modularity of the building elements, the framework of convex and concave building elements is preferably identical. This implies that the surface area of the connection surface of a convex building element is larger than the connection surface of a concave building element. Because the LED modules preferably completely cover the connection surface, the LED modules for convex building elements are preferably larger than the LED modules for concave building elements. Furthermore, the density of LEDs on a LED display for a convex building element can be different from the density of LEDs on a LED display for a concave building element because the LED module is bent in a different direction.

FIG. 5 shows an example of a simple modular construction wherein a convex and concave building element 1 and 1′ according to an embodiment of the invention is used. In the modular construction 2, a first straight connection side 9 of a first building element 1 is connected to a side edge of a straight building element 11. The opposite side edge of the straight building element 11 is connected to a second building element 1′, particularly to a second straight connection side 10′ thereof. Particularly when the straight building element 11 comprises a LED display, the figure illustrates that a LED display can substantially seamlessly run from one element to another element making curves in multiple directions.

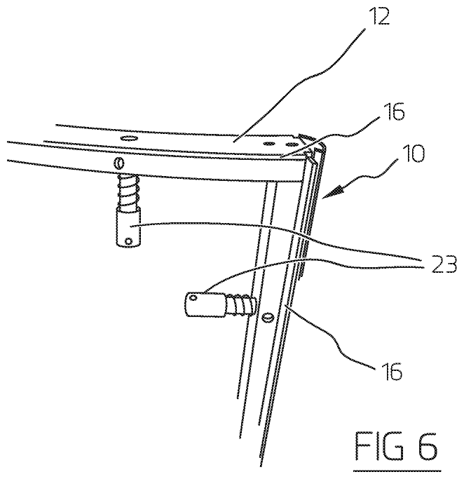

FIG. 6 shows a detail of a back side corner of a building element of an embodiment of the invention. The figure shows part of the first curved connection side 12 and the second straight connection side 10. The figure further shows the spring loaded pins with handles which are part of the complementary connector elements 23 described above. The figure further shows the groove 16 provided at the back side of the building element 1 running around the periphery of the building element 1. At the outer side of the groove 16, a peripheral edge is provided defining the total thickness of the building element. At the inner side of the groove 16, preferably an abutment is provided which is at least partially recessed with respect to the peripheral edge. This allows a back cover plate to be placed against the abutment and in alignment with the peripheral edge.

A person having ordinary skill in the art would appreciate that any of the various illustrative elements, logical blocks, modules, processors, means, circuits, and algorithm steps described in connection with the aspects disclosed herein may be implemented as electronic hardware (e.g., a digital implementation, an analog implementation, or a combination of the two, which may be designed using source coding or some other technique), various forms of program or design code incorporating instructions (which may be referred to herein, for convenience, as “software” or a “software module), or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. Building element for a modular construction, the building element comprising:
at least one LED module; and
a curved frame with a connection surface for the at least one LED module, wherein the LED module comprises a flexible substrate one side of which is provided with a LED display and the other side of which is provided with connection means to connect the flexible substrate with the curved frame.

2. The building element of claim 1, wherein the curved frame is curved around an axis over about 360/N degrees, wherein N is a natural number between two and ten, preferably four.

3. The building element of claim 2, wherein the curved frame extends between two straight connection sides, which straight connection sides are provided with connection means to enable interconnection of adjacent curved frames.

4. The building element of claim 3, wherein the straight connection sides are compatible with adjacent non-curved elements.

5. The building element of the claim 2, wherein the curved frame extends between two curved connection sides, which curved connection sides are provided with connection means to enable interconnection of adjacent curved frames

6. The building element of claim 1, wherein the at least one LED module comprises M identical LED modules, wherein M is a natural number between two and ten, preferably four.

7. The building element of claim 6, wherein each LED module comprises multiple magnets forming the connection means and wherein the curved frame comprises a magnetic surface to allow the LED modules to magnetically connect with the curved frame.

8. The building element of claim 6, wherein each LED module comprises positioning pins extending from the other side of the flexible substrate, the curved frame comprises perforations compatible with the positioning pins to enable positioning of the LED modules on the curved frame.

9. The building element of claim 1, wherein the curved frame comprises, opposite to the connection surface, a back surface, the back surface being provided with a groove extending around the periphery of the back surface to enable mounting of a back cover.

10. The building element of claim 9, wherein the back surface is additionally provided with handles to facilitate handling of the building element.

11. The building element of claim 9, wherein the back surface is provided with a power module for powering and controlling the LED modules.

12. The building element of claim 11, wherein the power module comprises a power input connection, a power throughput connection and comprises a signal input connection and a signal throughput connection.

13. The building element of claim 8, wherein the back surface is recessed with respect to a peripheral edge to enable a plate with a predetermined thickness to be mounted within the boundaries of the peripheral edge.

14. The building element of claim 1, wherein the connection surface is provided with an opening dimensioned to enable installing the building element from the front.

15. The building element of claim 1, wherein the curved frame comprises at least two support elements preventing the LED modules, when the curved frame is placed on a flat ground surface, to touch the ground.

16. The building element of claim 1, wherein the connection surface is convex.

17. The building element of claim 1, wherein the connection surface is concave.

18. A building element comprising:
a curved frame; and
an LED module removably coupled to the curved frame,
wherein the curved frame comprises:
a plate element;
a first straight connection side and a second straight connection side disposed along a pair of opposing parallel lateral edges of the plate element; and
a first curved connection side and a second curved connection side disposed along a pair of opposing parallel longitudinal edges of the plate element.

19. A modular building element system comprising:
a plurality of building elements;
means for coupling the plurality of building elements together; and
at least one LED module coupled to each of the plurality of building elements,
wherein each of the plurality of building elements comprises a curved frame with at least one connection surface configured to couple to the at least one LED module, and
wherein the at least one LED module coupled to each of the plurality of building elements comprises an LED display and means for coupling the at least one LED module to the curved frame.

20. The modular building element system of claim 19 wherein the means for coupling the plurality of building elements together comprises a straight building element disposed between at least two of the plurality of building elements.
